(19) United States
(12) Patent Application Publication
(10) Pub. No.: US 2026/0173736 A1
(43) Pub. Date: Jun. 18, 2026

(54) Display Panel

(71) Applicant: LG Display Co., Ltd., Seoul (KR)

(72) Inventors: Saemi Park, Busan (KR); Yeonsuk Kang, Seoul (KR); Goeun Lim, Mokpo-si (KR); Heesu Byeon, Paju-si (KR)

(21) Appl. No.: 19/182,176

(22) Filed: Apr. 17, 2025

(30) Foreign Application Priority Data
Dec. 18, 2024 (KR) 10-2024-0189984

(51) Int. Cl. H10K 59/80; H10K 59/38

(52) U.S. Cl. CPC H10K 59/879; H10K 59/38

(57) ABSTRACT

A display panel includes a lens layer. A pattern layer is formed on a surface of the lens layer. The pattern layer minimizes or at least reduces light extraction degradation while mitigating excessive light concentration effects from the lens layer. Thus, color viewing angle of the display panel is improved.

### CROSS REFERENCE TO RELATED APPLICATION

The present application claims priority to Republic of Korea Patent Application No. 10-2024-0189984 filed on Dec. 18, 2024, which is hereby incorporated by reference in its entirety.

### BACKGROUND

This specification relates to a display panel capable of improving a color viewing angle.

A display device is implemented in various forms, including television, monitor, smartphone, tablet personal computer (PC), laptop, and wearable device.

Among display apparatuses that display various information as images, the organic light-emitting display (OLED) features a self-emitting light-emitting element, offering advantages such as fast response time, high luminous efficiency, high luminance, wide viewing angles, excellent contrast ratio, and accurate color reproduction.

As demand for high-quality images increases, development of high-resolution display apparatuses progresses actively.

### SUMMARY

The display device is formed using organic light-emitting diode on silicon (OLEDoS) technology, a technique for forming OLED on a silicon substrate. Typically, OLEDoS utilizes a silicon wafer instead of glass or plastic substrates, enabling production of higher-resolution, higher-density display devices.

Applying a microcavity structure to a display device with such an OLEDoS structure enhances display efficiency and improves color expression. The microcavity structure is a technology that amplifies light of specific wavelengths in an organic light-emitting display to improve color reproducibility. The microcavity structure, composed of a thin dielectric layer and a reflective layer, resonates and reinforces light of specific wavelengths, amplifying the light emission efficiency in the OLED structure.

For example, a display device with an OLEDoS structure controls the emission wavelength of each sub-pixel by varying the thickness of the insulating layer, a dielectric layer disposed beneath a white organic light-emitting element (WOLED). On such an insulating layer, organic materials constituting the white organic light-emitting element are uniformly deposited on the same plane.

Such a display device structurally emits light with a mixture of main peaks and various sub-peaks. In this case, a color filter disposed above the organic light-emitting element under frontal viewing conditions removes most sub-peaks, generally enabling desired color expression; however, as the viewing angle increases, the light path inside the display device, namely the cavity length, changes, potentially distorting the emission spectrum. This results in a weakening of the main peak intensity and relative strengthening of sub-peaks, possibly causing a degradation in color viewing angle characteristics.

Meanwhile, to improve the light efficiency of specific colors, a micro-lens array may be disposed above the color filter. The micro-lens array concentrates light emitted from the light-emitting element, enhancing light extraction efficiency. For instance, a micro-lens array may be disposed on a blue sub-pixel to improve blue light efficiency. However, due to the inherent properties of the micro-lens array, the process of focusing light in a specific direction may exacerbate optical distortion due to viewing angle changes. That is, while desired color gamut is maintained during frontal observation, side observation may result in light being focused at specific angles by the micro-lens array, potentially leading to more pronounced color distortion and degradation of color viewing angle characteristics.

Additionally, when subsequent processes such as cover glass bonding, encapsulation layer formation, polarizer bonding, and substrate bonding are performed after forming the micro-lens array, physical pressure or temperature changes may deform the lens shape or press parts of the micro-lens array, risking collapse of the fine structure. This leads to loss of intended optical properties and may simultaneously worsen color reproducibility, brightness uniformity, and viewing angle characteristics.

Consequently, the inventors of this specification have invented a display panel capable of improving color viewing angle through various experiments.

The objective of an embodiment of this specification is to provide a display panel capable of improving color viewing angle by minimizing light extraction degradation while mitigating excessive light concentration effects from a lens layer.

The objective of an embodiment of this specification is to provide a display panel capable of ensuring stable color reproducibility across a wide viewing angle range.

The objective of an embodiment of this specification is to provide a display panel capable of finely dispersing light to aid in maintaining color balance.

The objective of an embodiment of this specification is to provide a display panel capable of reducing color distortion at specific angles by inducing light diffusion.

The objective of an embodiment of this specification is to provide a display panel capable of controlling optical paths using differences in refractive index.

The objective of an embodiment of this specification is to provide a display panel capable of preventing collapse of the shape of a color filter or lens layer due to pressure during subsequent processes.

The objective of an embodiment of this specification is to provide a display panel capable of suppressing color mixing that may occur due to light scattering.

The objective of an embodiment of this specification is to provide a display panel capable of enhancing the protective role of the lens layer.

The objective of an embodiment of this specification is to provide a display panel capable of maximizing the effect of the lens layer on specific sub-pixels.

The objective of an embodiment of this specification is to provide a display panel capable of balancing improvements in light efficiency of specific colors with addressing degradation of color viewing angle characteristics.

The technical objects of the embodiments of this specification are not limited to the aforesaid, and other objects not described herein with be clearly understood by those skilled in the art from the descriptions below.

A display panel according to an embodiment of this specification includes a substrate comprising a plurality of sub-pixels, a light-emitting device layer disposed on the substrate, a plurality of color filter layers disposed on the light-emitting device layer, a lens layer having a concave shape disposed on one or more of the color filter layers, and a pattern layer formed on a surface of the lens layer.

The pattern layer may include a convex shape.

A surface roughness of the lens layer caused by the pattern layer may be greater than a surface roughness of the color filter layer.

The pattern layer may have an irregular pattern.

A refractive index of the pattern layer may be greater than a refractive index of the lens layer.

The display panel may further include an intermediate layer disposed between the pattern layer and the lens layer, wherein a refractive index of the intermediate layer may be greater than the refractive index of the pattern layer and less than the refractive index of the lens layer.

The pattern layer may include a plurality of air gaps.

The display panel may further include a support portion disposed on the color filter layer, wherein the support portion may be disposed between adjacent color filter layers and is located in the same layer as the lens layer.

The support portion may include a light-absorbing material.

A height of the support portion may be greater than a height of the lens layer.

The display panel may further include a plurality of reflective electrodes disposed between the substrate and the light-emitting device layer, a first electrode disposed between the light-emitting device layer and the reflective electrodes, and a second electrode disposed on the light-emitting device layer, wherein distances between the reflective electrode and the second electrode differ depending on the colors of the corresponding sub-pixels.

A display panel according to another embodiment of this specification includes a substrate including a plurality of sub-pixels, a light-emitting device layer disposed on the substrate, a plurality of color filter layers disposed on the light-emitting device layer, a lens layer disposed on one or more of the color filter layers, and a pattern layer formed on a surface of the lens layer, wherein the plurality of sub-pixels includes a first sub-pixel, a second sub-pixel, and a third sub-pixel, and the lens layer is disposed on the first sub-pixel and the second sub-pixel.

The area of the third sub-pixel may be greater than the area of the first sub-pixel and the area of the second sub-pixel.

the color filter layer may include a first color filter layer corresponding to the first sub-pixel, a second color filter layer corresponding to the second sub-pixel, and a third color filter layer corresponding to the third sub-pixel, wherein a height of the third color filter layer may be greater than a height of the first color filter layer and a height of the second color filter layer.

The first sub-pixel may be a red sub-pixel, the second sub-pixel may be a green sub-pixel, and the third sub-pixel may be a blue sub-pixel.

The height of the third color filter layer may be greater than the height of the lens layer.

The display panel may further include a plurality of reflective electrodes disposed between the substrate and the light-emitting device layer, a first electrode disposed between the light-emitting device layer and the reflective electrodes, and a second electrode disposed on the light-emitting device layer, wherein distances between the reflective electrode and the second electrode differ depending on the colors of the corresponding sub-pixels.

According to an embodiment of this specification, forming a pattern layer on the surface of the lens layer minimizes or at least reduces degradation in light extraction and alleviates excessive light focusing caused by the lens layer, thereby improving color viewing angle.

According to an embodiment of this specification, the pattern layer formed above the lens layer disperses the light path and suppresses the emergence of sub-peaks at wider viewing angles, ensuring stable color reproducibility across a wider viewing angle range. According to an embodiment of this specification, ensuring stable color reproducibility in the display panel enables implementation of a low-power display panel, thereby reducing power consumption.

According to an embodiment of this specification, the pattern layer formed above a concave lens layer includes a convex shape, creating a concave-convex composite structure that delicately diffuses light to prevent concentration in a specific direction, aiding in maintaining color balance.

According to an embodiment of this specification, forming a pattern layer with predetermined surface roughness or irregular patterns on the surface of the lens layer induces light diffusion, reducing color distortion at specific angles. This contributes to maintaining the desired color spectrum even when observed from various viewing angles.

According to an embodiment of this specification, forming the pattern layer with a refractive index greater than that of the lens layer allows light to refract further in the pattern layer, controlling excessive concentration in one direction, thereby utilizing refractive index differences to control the optical path.

According to an embodiment of this specification, inserting an intermediate layer between the pattern layer and the lens layer and setting the refractive index of the intermediate layer between that of the pattern layer and the lens layer enables more precise optical path control. This controls sub-peaks and reduces color deviation across various observation angles.

According to an embodiment of this specification, incorporating air gaps within the pattern layer scatters or disperses light colliding in the air gaps. This reduces light concentration in the lens layer and further mitigates color distortion due to viewing angle changes.

According to an embodiment of this specification, disposing a support portion with a predetermined height between adjacent color filter layers prevents deformation or collapse of the color filter or lens layer under pressure during subsequent processes, such as cover glass bonding. This ensures the display panel stably maintains physical and optical properties.

According to an embodiment of this specification, the support portion disposed between adjacent color filter layers includes a light-absorbing material, suppressing color mixing due to light scattering and maintaining color purity.

According to an embodiment of this specification, setting the height of the support portion higher than the lens layer ensures the support portion contacts first during external pressure, enhancing the protective role of the lens layer.

According to an embodiment of this specification, disposing a lens layer with a pattern layer formed on its surface on specific sub-pixels maximizes the optical effect of the lens layer on those specific sub-pixels.

According to an embodiment of this specification, for sub-pixels without a lens layer having a pattern layer on its surface, forming the color filter with a greater height than that of other sub-pixels strikes a balance between enhancing light efficiency for specific colors and mitigating deterioration in color viewing angle characteristics. According to an embodiment of this specification, improving the efficiency of the display panel enables implementation of a low-power display panel, thereby reducing power consumption.

According to an embodiment of this specification, for sub-pixels without a lens layer having a pattern layer on its surface, forming the color filter with a greater height prevents the color filter or lens layer of other sub-pixels from collapsing due to pressure during subsequent processes, such as cover glass bonding. This ensures the display panel stably maintains physical and optical properties.

In addition to the aforementioned effects, other advantageous effects of the present invention will be provided along with the detailed description of the invention.

### BRIEF DESCRIPTION OF THE DRAWINGS

FIG. 1 is a schematic plan view of a display panel according to an embodiment;

FIG. 2 is a cross-sectional view taken along line I-I′ of FIG. 1 according to an embodiment;

FIG. 3 is a cross-sectional view taken along line II-II′ of FIG. 1 that illustrates the process of forming the first color filter and the third lower color filter according to an embodiment;

FIG. 4 is a cross-sectional view taken along line II-II′ of FIG. 1 that illustrates the process of forming a lens layer on the first color filter and a third upper color filter on the third lower color filter according to an embodiment;

FIG. 5 is a cross-sectional view taken along line III-III′ of FIG. 1 where a support portion is disposed between adjacent color filters according to an embodiment;

FIG. 6 is a cross-sectional view taken along line III-III′ of FIG. 1 where a support portion is disposed between adjacent color filters according to another embodiment;

FIG. 7 is a cross-sectional view taken along line III-III′ of FIG. 1 where a support portion is disposed between adjacent color filters according to yet another embodiment;

FIG. 8 is a cross-sectional view taken along line IV-IV′ of FIG. 1 where a support portion is not disposed between adjacent color filters according to an embodiment; and

FIG. 9 is a cross-sectional view taken along line IV-IV′ of FIG. 1 where a support portion is not disposed between adjacent color filters according to another embodiment.

### DETAILED DESCRIPTION

Advantages and features disclosed in this specification and methods of accomplishing the same may be understood more readily by reference to the detailed description of embodiments that will be made hereinafter with reference to the accompanying drawings. However, this specification is not limited to the embodiments disclosed below and may be implemented in various different forms; these embodiments are provided merely to ensure that the disclosure of this specification is complete and to fully inform those of ordinary skill in the art of the scope of the invention, with this specification being defined solely by the scope of the claims.

The shapes, sizes, ratios, angles, numbers and the like illustrated in the drawings to describe embodiments of the specification are merely exemplary, and thus, the specification is not limited thereto. Throughout the specification, the same reference numerals refer to the same components. In addition, detailed descriptions of well-known technologies may be omitted in the specification to avoid obscuring the subject matter of the specification. When terms such as “comprises,” “has,” “includes,” or “is made up of” are used in this specification, it should be understood that unless “only” is specifically used, additional elements or steps can be included. Unless otherwise explicitly stated, when a component is expressed in the singular form, it is intended to encompass the plural form as well.

In interpreting the components, it is construed to include a margin of error even in the absence of explicit description. In the case of describing positional relationships, for example, when the positional relationship between two components is described using terms such as “on,’ “on top of,” “below,” or “beside,” one or more other components may be positioned between the two components unless “directly” or “immediately” is specified.

When describing temporal relationships, expressions such as “after,” “following,” “next,” or “before” may indicate a sequence of events, and unless “immediately” or “directly” is used, non-continuous cases may also be included.

Terms like “first,” “second,” etc., are used to describe various components, but these components are not limited by these terms. These terms are merely used for distinguishing one component from the other components. Therefore, the first component mentioned hereinafter may be the second component in the technical sense of this specification.

The various features of the embodiments of the disclosure can combined or assembled together, either partially or entirely, in a technically diverse manner, and each embodiment can be independently implemented or in conjunction with related embodiments.

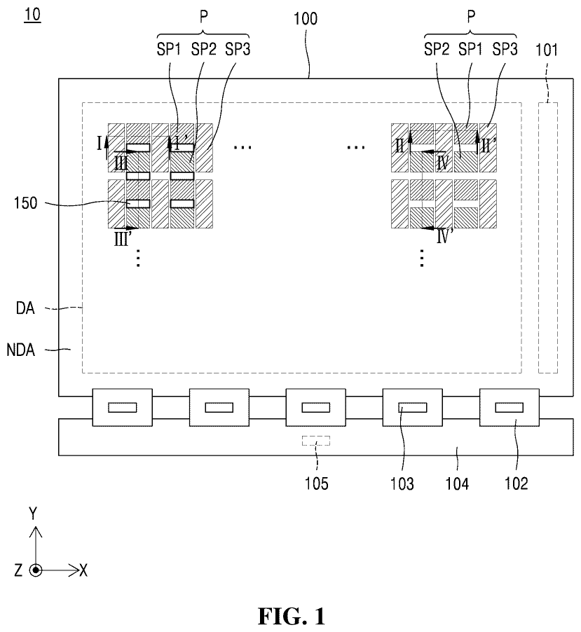

Hereinafter, a display panel and display device according to an embodiment of this specification are described in detail with reference to FIG. 1. The display device described below is exemplified as an organic light-emitting diode display device, but is not limited thereto.

The display panel 10 includes a substrate 100 including a display area DA and a non-display area NDA surrounding the display area DA. The display panel 10 includes a substrate 100, a source driving integrated circuit (IC) 103, a flexible film 102, a circuit board 104, and a timing controller 105.

In the display area DA on the substrate 100, a plurality of data lines extending in a first direction and a plurality of gate lines extending in a second direction intersecting the first direction cross to define areas, each containing a plurality of sub-pixels SP1, SP2, and SP3. In this specification, the first direction is the X-axis direction, the second direction is the Y-axis direction, and the Z-axis direction is perpendicular to the X-axis and Y-axis. Additionally, in this specification, one pixel P is exemplified as including a first sub-pixel SP1, a second sub-pixel SP2, and a third sub-pixel SP3, but is not limited thereto, and one pixel P may include additional sub-pixels.

Each of the sub-pixel SP1, SP2, and SP3 is implemented to emit light of the same color per sub-pixel, such as white light, or to emit different colors per sub-pixel, such as red, green, or blue light. Hereinafter, the first sub-pixel SP1 is exemplified as a red sub-pixel emitting red, the second sub-pixel SP2 as a green sub-pixel emitting green, and the third sub-pixel SP3 as a blue sub-pixel emitting blue. The plurality of sub-pixels SP1, SP2, and SP3 are arranged in a matrix form with a plurality of rows and columns.

The plurality of sub-pixels may have an asymmetrical arrangement. For example, the plurality of sub-pixels may be arranged in an S-stripe form. For instance, the area of the third sub-pixel SP3 is set larger than the areas of the first sub-pixel SP1 and the second sub-pixel SP2. This enhances the light efficiency of the color corresponding to the third sub-pixel SP3. For example, the length of the third sub-pixel SP3 extending in one direction is set equal to or greater than the sum of the lengths of the first sub-pixel SP1 and the second sub-pixel SP2 extending in one direction. However, this is not limited thereto, and the plurality of sub-pixels may be formed in a stripe structure where each sub-pixel is arranged linearly in a vertical or horizontal direction.

In the non-display area NDA on the substrate 100, a gate driver 101 is disposed on one or both sides of the display area DA. The gate driver 101 is implemented in a gate-in-panel (GIP) manner. The gate driver 101 supplies gate signals to the gate lines according to gate control signals input from the timing controller 105.

The source driving integrated circuit 103 receives digital video data and source control signals from the timing controller 105. The source driving integrated circuit 103 converts the digital video data into analog data voltages according to the source control signals and supplies them to the data lines. The source driving integrated circuit 103 is manufactured as a chip-on-film (COF) or chip-on-plastic (COP) driving chip and mounted on a plurality of flexible films 102. The circuit board 104 is attached to the plurality of flexible films 102. The circuit board 104 has multiple circuits implemented as driving chips, such as the timing controller 105, mounted thereon.

The timing controller 105 receives digital video data and timing signals from an external system board through a cable of the circuit board 104. The timing controller 105 supplies a gate control signal for controlling the operation timing of the gate driver 101 and a source control signal for controlling the source driving integrated circuits 103 based on the timing signals.

Meanwhile, a support portion 150 is formed between each sub-pixel. The support portion 150 prevents or at least reduces deformation of the lens layer 140, described later, due to pressure. For example, the support portion 150 is disposed between the adjacent first sub-pixel SP1 and second sub-pixel SP2. The support portion 150 disposed between the first sub-pixel SP1 and the second sub-pixel SP2 is arranged regularly, but is not limited thereto and may be arranged irregularly.

For example, the support portion 150 is disposed between the first sub-pixel SP1 and the second sub-pixel SP2 within one pixel P. In another example, the support portion 150 is disposed not only between the first sub-pixel SP1 and the second sub-pixel SP2 within one pixel P, but also between the first sub-pixel SP1 and the second sub-pixel SP2 located in different pixels P. In yet another example, the support portion 150 is not disposed between the first sub-pixel SP1 and the second sub-pixel SP 2 in some pixels P. For instance, the support portion 150 is disposed every 10 to 20 pixels P. The support portion 150 is described in detail later.

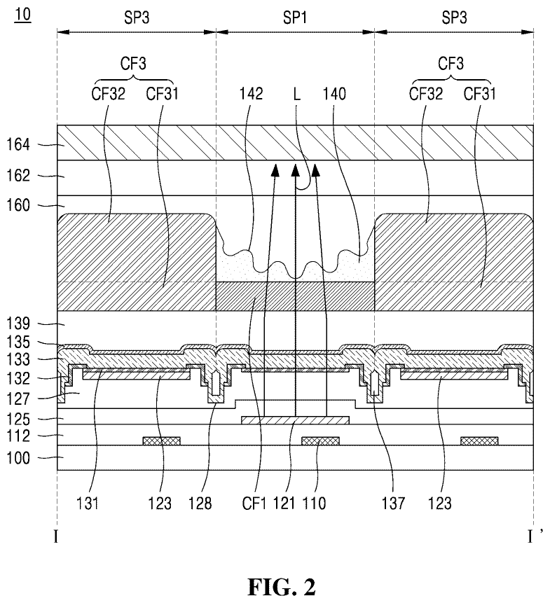

Hereinafter, with reference to FIGS. 2 to 9, the stacked structure of the display panel 10 according to various embodiments is described based on cross-sectional views.

The substrate 100 is made of glass or plastic such as polyimide, but is not limited thereto and may be made of a semiconductor material such as a silicon wafer. For example, the substrate 100 is a single-crystal silicon wafer formed by growing single-crystal silicon, but may be a wafer composed of various semiconductor materials. Hereinafter, an OLEDoS (OLED on Si wafer) structure, where a light-emitting device layer 133 including an organic light-emitting element is disposed on a silicon wafer substrate 100, is described as an embodiment, but is not limited thereto.

A circuit portion 110 is disposed on the substrate 100. Each of the sub-pixels SP1, SP2, and SP3 constituting the display panel 10 may have a circuit portion 110 disposed therein. The circuit portion 110 is electrically connected to a light-emitting device layer disposed on the circuit portion 110. For example, the circuit portion 110 includes various circuit-related elements, such as signal lines like gate lines and data lines, thin-film transistors, and storage capacitors. The thin-film transistor includes switching thin-film transistors, driving thin-film transistors, and sensing thin-film transistors, but is not limited thereto and may include complementary metal oxide semiconductor (CMOS) transistors.

The display panel 10 further includes a circuit portion insulating layer 112, a first reflective electrode 121, a first insulating layer 125, a second reflective electrode 122, a second insulating layer 127, and a third reflective electrode 123 disposed on the circuit portion 110.

The circuit portion insulating layer 112, the first insulating layer 125, and the second insulating layer 127 are each formed as a single layer or multiple layers of an inorganic film, such as silicon nitride, aluminum nitride, zirconium nitride, titanium nitride, hafnium nitride, tantalum nitride, silicon oxide, aluminum oxide, or titanium oxide, but are not limited thereto and may be formed as a single layer or multiple layers of an organic film, such as acryl resin, epoxy resin, phenolic resin, polyamide resin, or polyimide resin.

The first reflective electrode 121, the second reflective electrode 122, and the third reflective electrode 123 include a metal material with high reflectivity and, for example, are made of silver (Ag) or a metal material including silver (Ag), but are not limited thereto.

A circuit portion insulating layer 112 is disposed on the circuit portion 110 to cover the entire surface of the substrate 100. A first reflective electrode 121 is disposed on the circuit portion insulating layer 112 in the first sub-pixel SP1. That is, each of the plurality of first sub-pixels SP1 has a respective first reflective electrode 121 disposed therein.

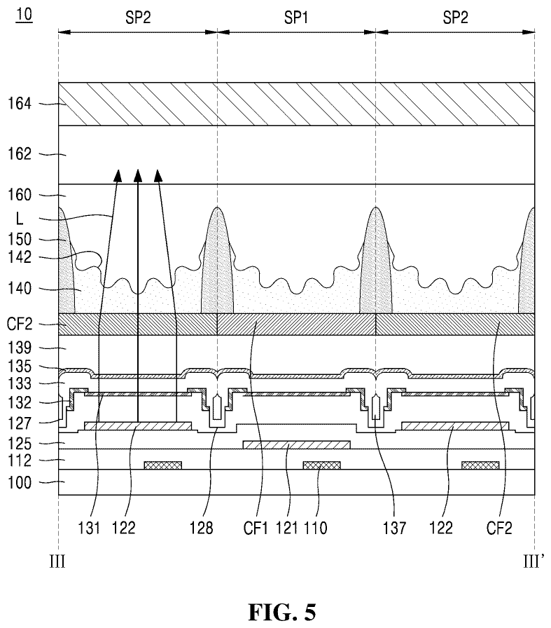

A first insulating layer 125 is disposed on the first reflective electrode 121 to cover the entire surface of the substrate 100. A second reflective electrode 122 is disposed on the first insulating layer 125 in the second sub-pixel SP2 (shown in FIG. 5). That is, each of the plurality of second sub-pixels SP2 has a respective second reflective electrode 122 disposed therein.

A second insulating layer 127 is disposed on the second reflective electrode 122 to cover the entire surface of the substrate 100. A third reflective electrode 123 is disposed on the second insulating layer 127 in the third sub-pixel SP3. That is, each of the plurality of third sub-pixels SP3 has a respective third reflective electrode 123 disposed therein.

A first electrode 131 is disposed on each of the first reflective electrode 121, the second reflective electrode 122, and the third reflective electrode 123 arranged as such. That is, each of the plurality of sub-pixels has a respective first electrode 131 disposed therein. The first electrode 131 is electrically connected to a light-emitting device layer 133, described later, and functions as an anode electrode. For example, the first electrode 131 includes a transparent conductive material or a semi-transmissive metal material, but is not limited thereto.

The first electrode 131 disposed on the third reflective electrode 123 may directly contact the third reflective electrode 123, but is not limited thereto. For example, a third insulating layer formed on the third reflective electrode 123 to cover the entire surface of the substrate 100 is additionally disposed between the third reflective electrode 123 and the first electrode 131, such that the third reflective electrode 123 and the first electrode 131 are arranged spaced apart by a predetermined distance without contacting each other.

The first electrodes 131 disposed between adjacent sub-pixels are arranged to be spaced apart from each other. A bank layer 132 is disposed on the first electrode 131. The bank layer 132 is formed to cover the ends of the first electrode 131, preventing current concentration at the ends of the first electrode 131. The bank layer 132 is composed of a single layer or multiple layers of an insulating material made of an inorganic material such as silicon nitride (SiNx) or silicon oxide (SiOx), but is not limited thereto. Additionally, the bank layer 132 may be made of an organic material and, for example, may include a material such as polyimide, acryl, or benzocyclobutene-based resin. The bank layer 132 may also be implemented as a black bank including a black material. The bank layer 132 may also be referred to as a fence.

A trench portion 128 is formed between bank layers 132 at the boundaries between adjacent sub-pixels. The trench portion 128 is formed by removing a portion of the insulating layer. For example, the trench portion 128 is formed as a concave groove recessed downward with a predetermined left-right width and height in the second insulating layer 127. The trench portion 128 is formed at the boundary between adjacent sub-pixels.

A light-emitting device layer 133 is disposed on the first electrode 131. The light-emitting device layer 133 is composed of a single stack. However, this is not limited thereto, and the light-emitting device layer 133 may have a tandem structure with two stacks, including a first stack, a charge generation layer CGL, and a second stack, or a tandem structure with three or more stacks.

When the light-emitting device layer 133 is a single stack, it includes a hole injecting layer (HIL), a hole transporting layer HTL, an emitting material layer EML, an electron transporting layer ETL, and an electron injecting layer EIL.

When the light-emitting device layer 133 includes a first stack, a charge generation layer, and a second stack, the first stack includes a hole injecting layer HIL, a hole transporting layer HTL, an emitting material layer EML, and an electron transporting layer ETL, and the emitting material layer EML of the first stack emits one of red light, green light, blue light, or yellow light. The charge generation layer includes an N-type charge generation layer to supply electrons to the first stack and a P-type charge generation layer to supply holes to the second stack. The second stack includes a hole transporting layer HTL, an emitting material layer EML, an electron transporting layer ETL, and an electron injecting layer EIL, and the emitting material layer EML of the second stack emits one of red light, green light, blue light, or yellow light. The emitting material layer EML of the first stack and the emitting material layer EML of the second stack emit light of different colors, enabling the light-emitting device layer 133, including the first stack and the second stack, to emit white light.

The light-emitting device layer 133 disposed on the first electrode 131, including the bank layer 132, is formed across the entire surface of the substrate 100 to cover adjacent sub-pixels. In this case, the light-emitting device layer 133 is disposed to fill the trench portion 128. A void portion 137 with a hollow shape is formed inside the light-emitting device layer 133 in the trench portion 128. The void portion 137 serves to interrupt the horizontal connection of the charge generation layer CGL disposed among adjacent sub-pixels. As the void portion 137 is formed in the trench portion 128, lateral leakage current that may occur due to a short circuit of the charge generation layer CGL between neighboring sub-pixels is reduced.

A second electrode 135 is disposed on the light-emitting device layer 133. The second electrode 135 is formed across the entire surface of the substrate 100 to be commonly connected with the light-emitting device layer 133 covering all sub-pixels. Thus, the second electrode 135 may be referred to as a common electrode. The second electrode 135 is electrically connected to the light-emitting device layer 133 and functions as a cathode electrode. For example, the second electrode 135 includes a transparent conductive material, such as indium tin oxide (ITO) or indium zinc oxide (IZO), or a semi-transmissive conductive material, but is not limited thereto.

An encapsulation layer 139, blocking external moisture and oxygen, is formed on the second electrode 135. The encapsulation layer 139 includes an inorganic insulating film, such as silicon oxide (SiOx) or silicon nitride (SiNx), or an organic insulating film, such as acryl resin or epoxy resin, and may be formed as a single layer or multiple layers.

A color filter layer CF1, CF2, and CF3 is disposed on the encapsulation layer 139. For example, the color filter layer includes a red first color filter layer CF1 provided in the first sub-pixel SP1, a green second color filter layer CF2 provided in the second sub-pixel SP2, and a blue third color filter layer CF3 provided in the third sub-pixel SP3. For example, the first color filter layer CF1 includes a red pigment or red dye, the second color filter layer CF2 includes a green pigment or green dye, and the third color filter layer CF3 includes a blue pigment or blue dye. The color filter layer is made of an organic material with relatively high transmittance.

The light-emitting device layer 133 according to an embodiment of this specification is implemented to emit white light. Thus, in the first sub-pixel SP1, white light emitted from the light-emitting device layer 133 passes through the first color filter CF1, transmitting only red light; in the second sub-pixel SP2, white light emitted from the light-emitting device layer 133 passes through the second color filter CF2, transmitting only green light; and in the third sub-pixel SP3, white light emitted from the light-emitting device layer 133 passes through the third color filter CF3, transmitting only blue light.

A planarization layer 160 is disposed on the color filter layer CF1, CF2, and CF3. The planarization layer 160 is made of an organic material. A cover layer 164 is disposed on the planarization layer 160. For example, the cover layer 164 is a cover glass made of glass material. The cover layer 164 is disposed on the planarization layer 160 via an adhesive layer 162.

The first reflective electrode 121, the second reflective electrode 122, and the third reflective electrode 123 reflect light emitted from the light-emitting device layer 133 upward toward the second electrode 135. That is, light emitted from the light-emitting device layer 133 is reflected and reinforced between the second electrode 135 and the first reflective electrode 121, the second reflective electrode 122, and the third reflective electrode 123, then passes through the second electrode 135 to be emitted outward.

Since the first reflective electrode 121, the second reflective electrode 122, and the third reflective electrode 123 are disposed on different layers, the distance from the first reflective electrode 121, the second reflective electrode 122, and the third reflective electrode 123 to the second electrode 135 is set differently for sub-pixels implementing different colors.

For example, the first distance from the first reflective electrode 121 to the second electrode 135 is greater than the second distance from the second reflective electrode 122 to the second electrode 135, and the second distance from the second reflective electrode 122 to the second electrode 135 is greater than the third distance from the third reflective electrode 123 to the second electrode 135. By forming the first distance, the second distance, and the third distance differently, light of different colors is extracted using microcavity characteristics.

Specifically, a longer distance from the reflective electrode to the second electrode 135 enhances the light extraction efficiency of longer-wavelength light, improving the light extraction efficiency of red light between the first reflective electrode 121 and the second electrode 135, while a shorter distance enhances the light extraction efficiency of shorter-wavelength light, improving the light extraction efficiency of blue light between the third reflective electrode 123 and the second electrode 135. Additionally, the distance from the second reflective electrode 122 to the second electrode 135 is shorter than the distance from the first reflective electrode 121 to the second electrode 135 and longer than the distance from the third reflective electrode 123 to the second electrode 135, enhancing the light extraction efficiency of green light.

Accordingly, according to the invention, applying a microcavity structure to the display panel 10 to emit light enhances the light extraction efficiency of red light in the first sub-pixel SP1, emitting red light; enhances the light extraction efficiency of green light in the second sub-pixel SP2, emitting green light; and enhances the light extraction efficiency of blue light in the third sub-pixel SP3, emitting blue light.

Meanwhile, a lens layer 140 is disposed on one or more color filter layers. For example, the lens layer 140 is disposed on two of the three sub-pixels. For instance, the lens layer 140 is disposed on the first sub-pixel SP1 and the second sub-pixel SP2. In another example, the lens layer 140 is also disposed on the second sub-pixel SP2 and the third sub-pixel SP3, or the first sub-pixel SP1 and the third sub-pixel SP3. In yet another example, the lens layer 140 is disposed on the first sub-pixel SP1, the second sub-pixel SP2, and the third sub-pixel SP3. Hereinafter, an embodiment where the lens layer 140 is disposed on the first sub-pixel SP1 and the second sub-pixel SP2 is described as a basis.

The lens layer 140 is formed to have a concave shape. That is, the lens layer 140 is formed such that its concave shape faces the direction in which light emitted from the light-emitting device layer 133 is emitted. The lens layer 140 is disposed on the first color filter layer CF1 and the second color filter layer CF2, respectively. For example, the lens layer 140 is disposed in contact with the first color filter layer CF1 and the second color filter layer CF2, respectively. For example, the lens layer 140 is formed through steps such as applying an organic insulating material, followed by exposure, development, and heat treatment. The refractive index of the lens layer 140 is set to be greater than the refractive index of the planarization layer 160 disposed on the lens layer 140. Accordingly, light emitted from the light-emitting device layer 133 passes through the first color filter layer CF1 and the second color filter layer CF2 and is then concentrated by the lens layer 140, enhancing light extraction efficiency.

A pattern layer 142 is formed on the surface of the lens layer 140. By performing a surface treatment on the surface of the lens layer 140 through a physical or chemical process, a pattern layer 142 with a predetermined pattern is formed on the surface of the lens layer 140. For example, the pattern formed on the pattern layer 142 is formed as a plurality of uneven patterns with fine sizes. The pattern layer 142 is disposed in contact with the upper surface of the lens layer 140. In this case, the pattern layer 142 is formed integrally with the lens layer 140. Light concentrated while passing through the lens layer 140 undergoes scattering in the pattern layer 142, allowing the emitted light to disperse outward. That is, the pattern layer 142 prevents excessive concentration of light passing through the lens layer 140 and mitigates the concentration effect.

According to an embodiment of this specification, forming a pattern layer 142 on the surface of the lens layer 140 minimizes or at least reduces light extraction degradation while mitigating excessive light concentration effects from the lens layer 140, thereby improving color viewing angle. Additionally, according to an embodiment of this specification, the pattern layer 142 formed above the lens layer 140 disperses the light path and suppresses the prominence of sub-peaks as the viewing angle increases, ensuring stable color reproducibility across a wider viewing angle range.

Referring to FIGS. 2 and 5, a pattern layer 142 according to an embodiment is formed to include a convex shape. Thus, a plurality of pattern layers 142 having a convex shape are formed on the lens layer 140, which overall has a concave shape. In this case, the convex shapes formed by the pattern layers 142 are formed regularly or with the same size, but are not limited thereto and may be formed irregularly or with different sizes.

According to an embodiment of this specification, the pattern layer 142 formed on the concave lens layer 140 includes a convex shape, creating a concave-convex composite structure that finely disperses light to prevent concentration in a specific direction, thereby aiding in maintaining color balance.

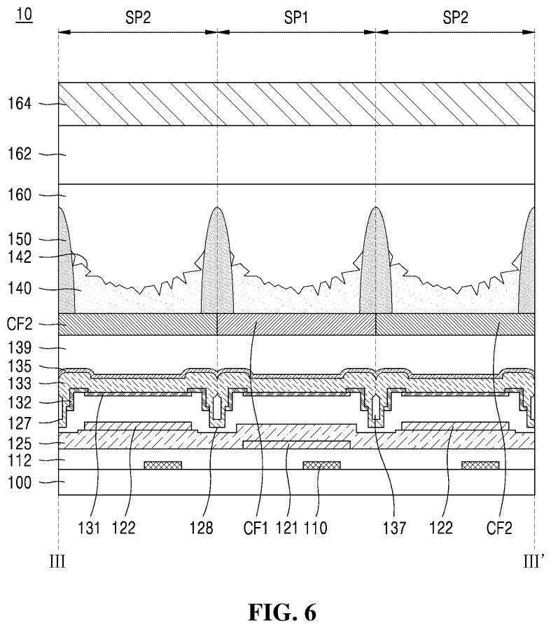

Referring to FIG. 6, a lens layer 140 according to another embodiment is imparted with a surface roughness within a predetermined range, thereby forming a pattern layer 142. For example, the surface of the lens layer 140 is subjected to surface treatment, such as etching, or physical surface damage treatment to impart a surface roughness with an irregular pattern, thereby forming the pattern layer 142. That is, the surface roughness of the surface-treated lens layer 140 is imparted by the pattern layer 142 formed through surface treatment. For instance, the surface roughness of the lens layer 140 with the pattern layer 142 formed through surface treatment is greater than the surface roughness of a lens layer 140 without surface treatment and without a pattern layer 142. Additionally, the surface roughness of the lens layer 140 with the pattern layer 142 formed through surface treatment is greater than the surface roughness of the color filter layer CF1, CF2, and CF3.

According to an embodiment of this specification, imparting a predetermined surface roughness or forming a pattern layer 142 with an irregular pattern on the surface of the lens layer 140 induces light diffusion, reducing color distortion at specific angles. This contributes to maintaining the desired color spectrum even when observed from various viewing angles.

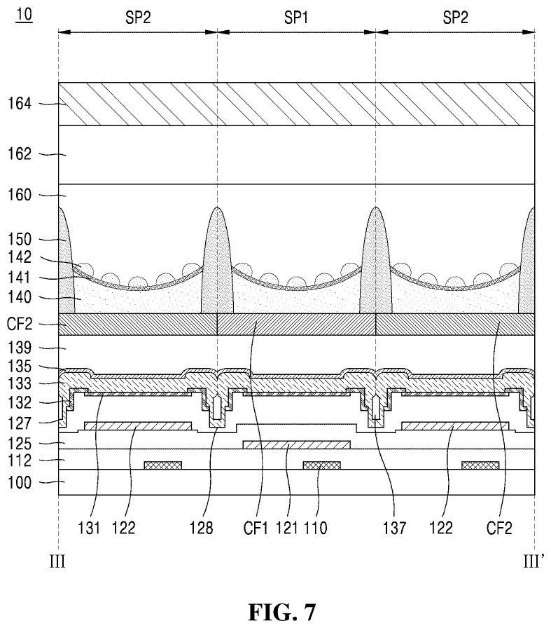

Referring to FIG. 7, a plurality of pattern layers 142 with a different refractive index from the lens layer 140 are formed on the lens layer 140 according to another embodiment. For example, a plurality of pattern layers 142 with a refractive index greater than that of the lens layer 140 are formed on the lens layer 140. Thus, the lens layer 140 and the pattern layer 142 may not be integral with each other. The pattern layer 142 is composed of a material with a different refractive index from the lens layer 140. In this case, the pattern layer 142 is formed in contact with the upper surface of the lens layer 140. The plurality of pattern layers 142 are arranged such that adjacent pattern layers 142 are spaced apart by a predetermined distance.

According to an embodiment of this specification, forming the refractive index of the pattern layer 142 greater than that of the lens layer 140 allows light to refract further in the pattern layer 142, controlling excessive concentration in one direction, thereby utilizing refractive index differences to control the optical path.

According to another embodiment, an intermediate layer 141 disposed between the pattern layer 142 and the lens layer 140 is further included. In this case, the refractive index of the intermediate layer 141 is greater than that of the pattern layer 142 and less than that of the lens layer 140. The intermediate layer 141 is formed on the surface of the lens layer 140, overall having a concave shape and a predetermined thickness. Thus, the lens layer 140, the intermediate layer 141, and the pattern layer 142 are stacked in sequence from bottom to top, contacting each other.

According to an embodiment of this specification, inserting an intermediate layer 141 between the pattern layer 142 and the lens layer 140 and setting the refractive index of the intermediate layer 141 between that of the pattern layer 142 and the lens layer 140 enables more precise optical path control. This controls sub-peaks and reduces color deviation across various observation angles.

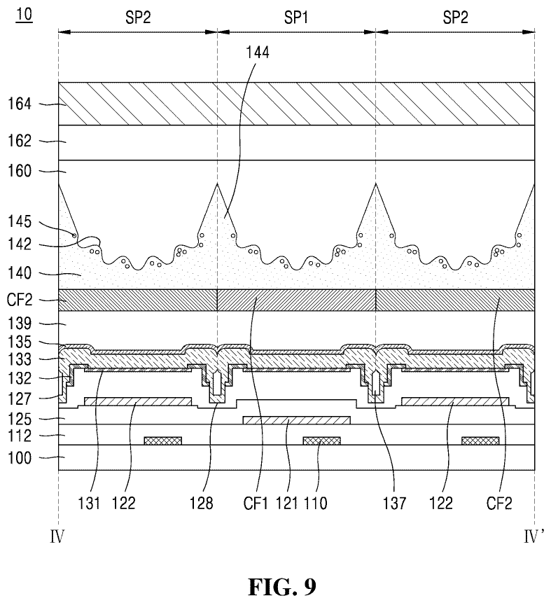

Referring to FIG. 9, the surface of a lens layer 140 according to another embodiment includes a plurality of air gaps 145. For example, the plurality of air gaps 145 are formed in a pattern layer 142 on the surface of the lens layer 140. The air gap 145 is a hollow containing trapped air. For instance, during the process of forming the lens layer 140 and the pattern layer 142, a thermal process forms the air gap 145 inside the pattern layer 142.

According to an embodiment of this specification, including air gaps 145 in the pattern layer 142 scatters or disperses light colliding in the air gaps 145. This reduces light concentration in the lens layer 140 and further mitigates color distortion due to viewing angle changes.

Meanwhile, referring to FIGS. 5 to 7, a support portion 150 is formed on the color filter layer CF1, CF2, and CF3. The support portion 150 is disposed between adjacent color filter layers CF1, CF2, and CF3. For example, the support portion 150 is disposed on the boundary between the first color filter layer CF1 and the second color filter layer CF2. Thus, a portion of the support portion 150 is disposed in the first sub-pixel SP1 where the first color filter layer CF1 is located, and the remaining portion of the support portion 150 is disposed in the second sub-pixel SP2 where the second color filter layer CF2 is located.

The support portion 150 is disposed on the same layer as the lens layer 140. Thus, the support portion 150 separates the lens layer 140 of the adjacent first sub-pixel SP1 and the lens layer 140 of the second sub-pixel SP2. The support portion 150 includes a light-absorbing material. For example, the support portion 150 is a black matrix.

According to an embodiment of this specification, the support portion 150 disposed between adjacent color filter layers includes a light-absorbing material, suppressing color mixing between adjacent sub-pixels due to light scattering, thereby maintaining color purity.

Additionally, the support portion 150 extends upward to be higher than the height of the lens layer 140. The width of the support portion 150 in the left-right direction may narrow from bottom to top, but is not limited thereto.

According to an embodiment of this specification, disposing a support portion 150 with a predetermined height between adjacent color filter layers prevents the color filter layer or the lens layer 140 from collapsing due to pressure during subsequent processes, such as cover glass bonding. This ensures the display panel stably maintains physical and optical properties.

According to an embodiment of this specification, setting the height of the support portion 150 higher than the lens layer 140 ensures that the support portion 150 contacts first during external pressure, enhancing the protective role of the lens layer 140.

Meanwhile, referring to FIG. 2, the height of the third color filter layer CF3, where the lens layer 140 is not disposed, is set higher than the height of the first color filter layer CF1 and the second color filter layer CF2, where the lens layer 140 is disposed. Additionally, the height of the third color filter layer CF3 is set higher than the height of the lens layer 140 formed on the first color filter layer CF1 and the second color filter layer CF2.

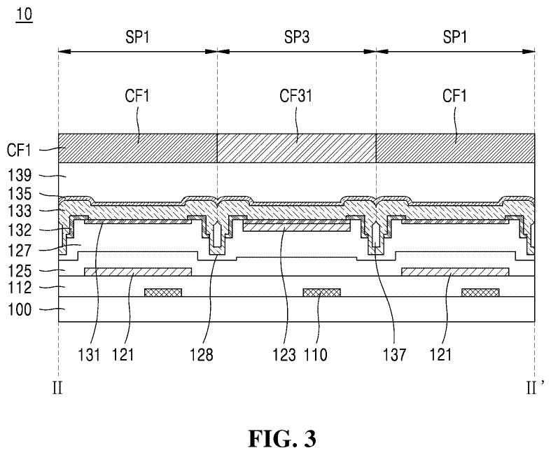

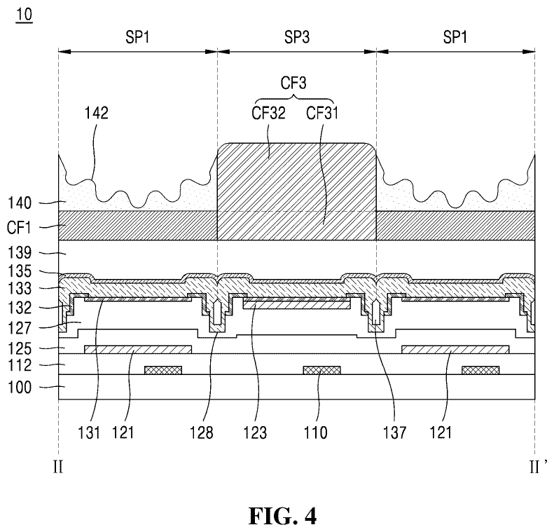

For example, the third color filter layer CF3 is formed through the following process. Referring to FIG. 3, the third lower color filter layer CF31 and the first color filter layer CF1 are formed on the same layer. In this case, the third lower color filter layer CF31 is formed to have the same height as the first color filter layer CF1. Referring to FIG. 4, a third upper color filter layer CF32 is formed on the third lower color filter layer CF31, and a lens layer 140 is formed on the first color filter layer CF1. The third upper color filter layer CF32 is formed to have an approximately convex shape, but is not limited thereto. In another example, the edge portion of the third upper color filter layer CF32 is formed to have a curved surface. Thus, the third color filter layer CF3, including the third lower color filter layer CF31 and the third upper color filter layer CF32 formed through a two-step process, is formed higher than the first color filter layer CF1 and the second color filter layer CF2. Additionally, the height of the third color filter layer CF3 is set greater than the sum of the height of the first color filter layer CF1 and the height of the lens layer 140, and the sum of the height of the second color filter layer CF2 and the height of the lens layer 140.

According to an embodiment of this specification, for a sub-pixel without a lens layer 140 having a pattern layer 142 on its surface, forming the color filter layer higher than other sub-pixels balances improvements in light efficiency of a specific color with addressing degradation of color viewing angle characteristics.

According to an embodiment of this specification, for a sub-pixel without a lens layer 140 having a pattern layer 142 on its surface, forming the color filter layer CF1, CF2, and CF3 higher prevents the color filter layer or lens layer 140 of other sub-pixels from collapsing due to pressure during subsequent processes, such as cover glass bonding. This ensures the display panel stably maintains physical and optical properties.

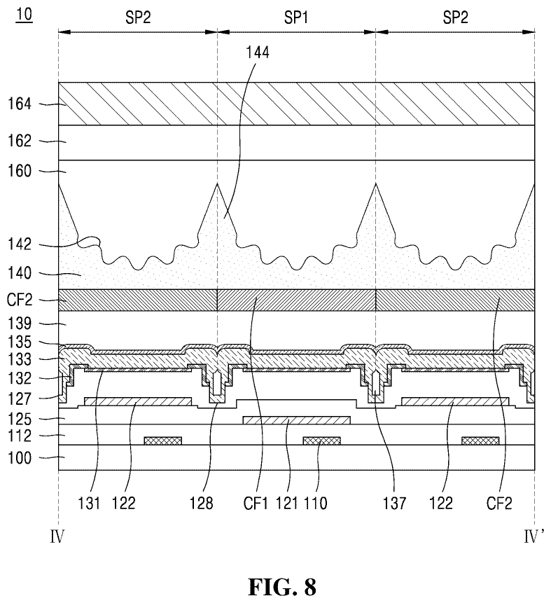

Referring to FIGS. 8 and 9, a support portion 150 may not be formed between the adjacent first sub-pixel SP1 and second sub-pixel SP2. In this case, the lens layers 140 disposed in adjacent sub-pixels are formed to be continuously connected to each other. In this case, a connection portion 144 connecting the adjacent lens layers 140 continuously is formed at the boundary between the first sub-pixel SP1 and the second sub-pixel SP2. Based on one sub-pixel, the connection portion 144 is formed to surround the sub-pixel, and the lens layer 140 disposed between adjacent connection portions 144 is formed to have a concave shape. Thus, the connection portion 144 is formed to extend upward.

According to an embodiment of this specification, the connection portion 144 continuously connecting adjacent lens layers 140 prevents the lens layer 140 from collapsing due to pressure during subsequent processes, such as cover glass bonding. This ensures the display panel stably maintains physical and optical properties.

As described above, the display panel can be applied to various types of display devices. For example, the display panel 10 according to an embodiment of this specification is included in a head-mounted display device. The head-mounted display device can provide images implementing virtual reality (VR) or augmented reality (AR) to the user, respectively.

Although embodiments of this specification have been described in detail with reference to the accompanying drawings, it should be noted that the specification is not necessarily limited to these embodiments and can be modified in various ways without departing from the scope of the technical concept of the invention. Therefore, the embodiments disclosed in this specification are not intended to limit but to describe the technical idea of the specification, and the scope of the technical idea of the specification is not limited by the embodiments. Therefore, it should be understood that the embodiments described above are exemplary and not limited in all aspects.

What is claimed is:

1. A display panel comprising:
a substrate comprising a plurality of sub-pixels;
a light-emitting device layer on the substrate;
a plurality of color filter layers on the light-emitting device layer;
a lens layer having a concave shape, the lens layer on one or more of the plurality of color filter layers; and
a pattern layer on a surface of the lens layer.

2. The display panel according to claim 1, wherein the pattern layer includes a convex shape.

3. The display panel according to claim 1, wherein a surface roughness of the lens layer caused by the pattern layer is greater than a surface roughness of a color filter layer from the plurality of color filter layers.

4. The display panel according to claim 3, wherein the pattern layer has an irregular pattern.

5. The display panel according to claim 1, wherein a refractive index of the pattern layer is greater than a refractive index of the lens layer.

6. The display panel according to claim 5, further comprising:
an intermediate layer between the pattern layer and the lens layer,
wherein a refractive index of the intermediate layer is greater than the refractive index of the pattern layer and less than the refractive index of the lens layer.

7. The display panel according to claim 1, wherein the pattern layer comprises a plurality of air gaps.

8. The display panel according to claim 1, further comprising:
a support portion on the plurality of color filter layers, the support portion between adjacent color filter layers from the plurality of color filter layers and located in a same layer as the lens layer.

9. The display panel of claim 8, wherein the support portion includes a light-absorbing material.

10. The display panel according to claim 8, wherein a height of the support portion is greater than a height of the lens layer.

11. The display panel according to claim 1, further comprising:
a plurality of reflective electrodes between the substrate and the light-emitting device layer;
a first electrode between the light-emitting device layer and the plurality of reflective electrodes; and
a second electrode on the light-emitting device layer,
wherein distances between a reflective electrode from the plurality of reflective electrodes and the second electrode differ depending on colors of corresponding sub-pixels from the plurality of sub-pixels.

12. A display panel comprising:
a substrate comprising a plurality of sub-pixels;
a light-emitting device layer on the substrate;
a plurality of color filter layers on the light-emitting device layer;
a lens layer on one or more of the plurality of color filter layers; and
a pattern layer on a surface of the lens layer,
wherein the plurality of sub-pixels includes a first sub-pixel, a second sub-pixel, and a third sub-pixel, and the lens layer is on the first sub-pixel and the second sub-pixel.

13. The display panel according to claim 12, wherein an area of the third sub-pixel is greater than an area of the first sub-pixel and an area of the second sub-pixel.

14. The display panel according to claim 12, wherein the plurality of color filter layers comprise:
a first color filter layer corresponding to the first sub-pixel;
a second color filter layer corresponding to the second sub-pixel; and
a third color filter layer corresponding to the third sub-pixel,
wherein a height of the third color filter layer is greater than a height of the first color filter layer and a height of the second color filter layer.

15. The display panel according to claim 14, wherein the first sub-pixel is a red sub-pixel, the second sub-pixel is a green sub-pixel, and the third sub-pixel is a blue sub-pixel.

16. The display panel according to claim 14, wherein the height of the third color filter layer is greater than the height of the lens layer.

17. The display panel according to claim 12, further comprising:
a plurality of reflective electrodes between the substrate and the light-emitting device layer;
a first electrode between the light-emitting device layer and the plurality of reflective electrodes; and
a second electrode on the light-emitting device layer,
wherein distances between a reflective electrode from the plurality of reflective electrodes and the second electrode differ depending on colors of corresponding sub-pixels from the plurality of sub-pixels.
